(19) United States
(12) Patent Application Publication
(10) Pub. No.: US 2014/0266280 A1
(43) Pub. Date: Sep. 18, 2014

(54) PROBE CARD, PROBE STRUCTURE AND METHOD FOR MANUFACTURING THE SAME

(71) Applicant: WIN Semiconductors Corp., Tao Yuan Shien (TW)

(72) Inventors: Shu Jeng YEH, Tao Yuan Shien (TW); Min Chang TU, Tao Yuan Shien (TW); Jo Chang WU, Tao Yuan Shien (TW); Hui Mei OU, Tao Yuan Shien (TW); Cheng Ching HSU, Tao Yuan Shien (TW)

(73) Assignee: WIN Semiconductors Corp., Tao Yuan Shien (TW)

(21) Appl. No.: 14/213,464

(22) Filed: Mar. 14, 2014

(30) Foreign Application Priority Data
Mar. 15, 2013 (TW) 102109206

(51) Int. Cl. G01R 1/067; G01R 3/00

(52) U.S. Cl. CPC G01R 1/067; G01R 3/00
USPC 324/755.11; 324/756.03; 427/430.1; 29/428; 205/122

(57) ABSTRACT

A probe structure is disclosed which includes a metal needle, a soft insulative tube and a metal layer. The metal needle has a first end-portion and a second end-portion opposite to each other. The first end-portion has a tip. The soft insulative tube has a through hole in which the metal needle is partially inserted. The tip of the metal needle protrudes from the through hole. The metal layer is coated on the outer surface of the soft insulative tube and is electrically isolated from the metal needle; the thickness of the metal layer has a thickness no larger than 10 micrometers. Therefore, good resilience and signal integrity could coexist in the probe structure. A probe card including several above-mentioned probe structures and a method for manufacturing the above-mentioned probe structure are also disclosed.

### PRIORITY

This application claims priority to Taiwan Patent Application No. 102109206 filed on Mar. 15, 2013, which is hereby incorporated herein by reference in its entirety.

### FIELD

The present invention relates to a probe card, a probe structure and a method for manufacturing the same, and more particularly, to a probe card and a probe structure that have a shielding function, and a method for manufacturing the same.

### BACKGROUND

As a connection medium between an electronic component under test (e.g., a wafer or a chip) and a tester, a probe card allows the tester to transmit a testing signal via the probe card to the small-sized electronic component to test electrical characteristics of the electronic component. Usually, three characteristics are considered in choosing a probe card in practice: the space transformer, the signal integrity and the practical production.

The preferred space transformer is where the metal needles of the probe card can be arranged more densely and the spacing between the metal needles can be made smaller so that the probe card can test an electronic component in which the metal pads are arranged more densely. The preferred signal integrity is when the testing signal is less liable to interference when passing through the metal needles of the probe card so that a more reliable testing result is obtained. The preferred practical production is to lower the costs for production, assembly, replacement or maintenance of the probe card, so the user can buy or use the probe card at a lower cost.

Probe cards may be preliminarily divided into lateral probe cards and vertical probe cards. The lateral probe cards may be sub-divided into the “Blade” type, the “Epoxy” type, etc., according to the producing methods. The vertical probe cards may be sub-divided into the “Cobra” type, the “Pogo” type, the “Membrane” type, the “MEMS” type etc., according to the producing methods. Each type of probe cards may be further sub-divided into shielded ones and unshielded ones. The characteristics of all these types are listed in the following two tables:

| | Fabri- | Unshielded | | | |
|---|---|---|---|---|---|
| | cation | Space transformer | | Production | |
| Type | method | Min. pitch | Probe density | Cost | Lead time |
| Lateral | Blade | Fair | Bad | Good | Good |
| | Epoxy | Good | Fair | Good | Good |
| Vertical | Cobra | Fair | Good | Good | Fair |
| | Pogo | Bad | Fair | Fair | Fair |
| | Membrane | Good | Fair | Bad | Bad |
| | MEMS | Good | Good | Bad | Bad |

| | | Shielded | | | |
|---|---|---|---|---|---|
| | | | Signal | | Space |
| | Fabri- | | integrity | Production | transformer |
| | cation | Shielding | Electrical | Additional | Additional |
| Type | method | type | improvement | cost | restriction |
| Lateral | Blade | Microstrip | Bad | Fair | Good |
| | | Coax | Good | Bad | Good |
| | Epoxy | Microstrip | Good | Good | Bad |
| | | Coaxial | Bad | Fair | Bad |
| Vertical | Cobra | Coax | N/a | N/a | N/a |
| | Pogo | Coax | Fair | Bad | Bad |
| | Membrane | Microstrip | Fair | Good | Good |
| | MEMS | N/a | N/a | N/a | N/a |

For an unshielded probe card, the impedance of the metal needles, signal coupling between the metal needles, or noise in the testing space will interfere with the testing signals passing through the metal needles of the probe card, which decreases the reliability of the testing results. When the electronic product (e.g., an integrated circuit (IC) chip) under testing operates at an increased speed or with an increased signal frequency, the signal interference problem will become more significant and must be improved. A way to improve this problem is to incorporate a shielding structure into the probe card. Usually, microstrips, coaxial cables or the like are used as such shielding structures. As an example, U.S. Pat. Nos. 4,871,964, 5,525,911, 5,565,788, 6,420,889 and 6,727,716 have proposed a shielding structure in the form of a coaxial cable. According to these patents, an insulative layer and a metal layer are sequentially covered on the outer surface of a metal needle to form the metal needle into a coaxial probe. Furthermore, shielding structures in the form of microstrips have been proposed in U.S. Pat. No. 4,791,363 and U.S. Pat. No. 5,382,898 and EP Patent NO. EP 0361779 A1.

When a shielding structure in the form of a coaxial cable is used, the front end-portion of the metal needle must protrude out of the insulative layer and the metal layer by a large distance without being covered by the insulative layer and the metal layer in order to keep the resilience of the front end-portion. The reason is that: if the front end-portion of the metal needle is covered by the metal layer that has a large thickness, the resilience of the front end-portion would be remarkably degraded; this makes it difficult for the front end-portion to be deformed to absorb or buffer the force generated when the tip of the metal needle strikes against the electronic component.

Because the front end-portion of the metal needle cannot be covered by the insulative layer and the metal layer, the testing signal is still liable to interference from the interaction between the front end-portions of individual metal needles. On the other hand, if the metal needle is covered by the insulative layer and the metal layer, the thickness of the metal needle would be increased significantly to result in an increased spacing between the individual metal needles, and this would degrade the space transformer of the probe card. Furthermore, a metal needle covered by the thick insulative layer and metal layer is liable to damage and must be replaced more frequently; this leads to an increase in cost. Moreover, the shielding structure in the form of a coaxial cable is only applicable to lateral needles but not to vertical needles.

Accordingly, a need exists in the art to provide an improved solution.

### SUMMARY

An objective of the present invention includes providing a probe card, a probe structure and a method for manufacturing the same which can improve the integrity of a testing signal, maintain the resilience of the probe structure and are applicable to vertical probe structures.

To achieve the aforesaid objective, the probe structure disclosed in certain embodiments comprises a metal needle, having a first end-portion and a second end-portion opposite to each other, wherein the first end-portion has a tip; a soft insulative tube, having a through hole in which the metal needle is partially inserted, wherein the tip of the metal needle protrudes from the through hole; and a metal layer, being coated on an outer surface of the soft insulative tube, being electrically isolated from the metal needle, and having a thickness no larger than 10 micrometers.

The probe card disclosed in certain embodiments comprises a probe fixture; and a plurality of the probe structures as described above, being held by the probe fixture, wherein the tips of the probe structures are exposed outside the probe fixture.

The method for manufacturing a probe structure disclosed in certain embodiments comprises providing a soft insulative tube which has a through hole; coating a metal layer with a thickness no larger than 10 micrometers on an outer surface of the soft insulative tube; and inserting a metal needle into the through hole of the soft insulative tube in such a way that a tip of the metal needle protrudes from the through hole.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a perspective view of a probe structure according to the first preferred embodiment of the present invention;

FIG. 2 is a cross sectional view of the probe structure according to the first preferred embodiment of the present invention;

FIG. 3 is a cross sectional view of a probe structure according to the second preferred embodiment of the present invention;

FIG. 4A is a bottom view of a probe card according to the third preferred embodiment of the present invention;

FIG. 4B is another bottom view of the probe card according to the third preferred embodiment of the present invention (a partially enlarged view of FIG. 4A);

FIG. 5 is a side view of the probe card according to the third preferred embodiment of the present invention;

FIGS. 6A to 6D are four side views of a probe card according to the fourth preferred embodiment of the present invention respectively;

FIGS. 7A and 7B are two side views of a probe card according to the fifth preferred embodiment of the present invention respectively;

FIGS. 8A to 8C are three schematic views of a method for manufacturing a probe structure according to the sixth preferred embodiment of the present invention;

FIG. 9A shows the testing result of the resilience of the probe structures according to the first preferred embodiment of the present invention;

FIG. 9B shows the testing result of the signal integrity of the probe card according to the third preferred embodiment of the present invention; and

FIG. 10 is a schematic view of a transistor under test.

### DETAILED DESCRIPTION

In the following descriptions, the present invention will be explained with reference to various example embodiments; nevertheless, these embodiments are not intended to limit the present invention to any specific example, environment, application, or particular implementation described herein. Therefore, descriptions of these example embodiments are only provided for purpose of illustration rather than to limit the present invention. The various features or aspects discussed herein can also be combined in additional combinations and embodiments, whether or not explicitly discussed herein, without departing from the scope of the invention.

FIGS. 1 and 2 show a perspective view and a cross sectional view of a probe structure according to the first preferred embodiment of the present invention respectively. In the first embodiment of the present invention, a probe structure 10 is proposed. The probe structure 10 is a lateral probe structure and can be used in a probe card (e.g., a probe card 1 shown in FIG. 4A that will be described later).

The probe structure 10 may comprise a metal needle 11, a soft insulative tube (or called a soft dielectric tube) 12 and a metal layer 13; the technical contents of the components will be sequentially described as follows.

The metal needle 11 may be a rod-shaped structure, and may be made of a metal with a good electrical conductivity and a good resilience, for example, beryllium copper, rhenium tungsten, Paliney 7 (a P7 alloy consisting of palladium, silver, gold, platinum and so on), or the like. The metal needle 11 has a first end-portion 111 and a second end-portion 112 opposite to each other. The first end-portion 111 further has a tip 1111 which can be used to contact a metal pad of an electronic component under testing (e.g., as shown in FIG. 4B described later). The second end-portion 112 of the metal needle 11 may be connected with a transmission line (e.g., as shown in FIG. 6A described later) to be electrically connected to components (not shown) of the probe card such as a substrate thereof. The second end-portion 112 may be electrically connected to the components of the probe card without using a transmission line (e.g., as shown in FIG. 5 described later).

The soft insulative tube 12 is formed of a material with a good insulativity (or a low dielectric constant). The material further makes the soft insulative tube 12 easily flexible; that is, the material can impart a good flexibility to the soft insulative tube 12. The manufacturing material may be, for example, polyimide or PTFE.

The soft insulative tube 12 has a through hole 121 in which the diameter may be larger than or equal to an outer diameter of the metal needle 11 so that the metal needle 11 can be partially inserted in the through hole 121. In other words, the metal needle 11 is partially covered by the soft insulative tube 12. The tip 1111 of the metal needle 11 protrudes from the through hole 121 without being covered by the soft insulative tube 12. Aside from the tip 1111, other parts of the first end-portion 111 may also optionally protrude from the through hole 121 depending on practical applications (as shown in FIG. 6A). In this embodiment, the first end-portion 111 protrudes from the through hole 121 only at the tip 111 thereof.

The metal layer 13 is made of a metal (e.g., nickel, gold, palladium or the like) with a good electrical conductivity. The metal layer 13 may be coated on an outer surface 122 of the soft insulative tube 12 through electrolysis plating, electroless plating, evaporating, sputtering or the like. The metal layer 13 is electrically isolated from the metal needle 11; that is, it is difficult for the metal layer 13 to be electrically connected with the metal needle 11. The metal layer 13 has a thickness T no larger than 10 micrometers (which are equal to about 0.39 mils); that is, the maximum value of the thickness T of the metal layer 13 is 10 micrometers or 0.39 mils.

Covering the metal needle 11 with the metal layer 13 and the soft insulative tube 12 can make a testing signal less liable to interference or distortion when being transmitted in the metal needle 11. On the other hand, because the thickness T of the metal layer 13 is at most 10 micrometers and the soft insulative tube 12 flexes easily, the metal layer 13 and the soft insulative tube 12 hardly affect or reduce the resilience of the metal needle 11. Thus, even though the first end-portion 111 of the metal needle 11 is not covered by the metal layer 13 and the soft insulative tube 12 only at the tip 1111, the overall resilience of the metal needle 11 is still not affected and can still buffer the impact generated when the tip 1111 strikes against the electronic component under testing or reduce the contact force of the tip 1111 on the electronic component under testing. The probe structure 10 absorbs the impacting force when touching the metal pad to avoid deformations and damages; however, if the impacting force generated when the probe structure 10 touches the metal pad exceeds a certain level, various restorable or non-restorable deformations or damages can still occur.

FIG. 9A illustrates four types of probe structures to be tested for resilience. The first type is a traditional probe structure (labeled as A in FIG. 9A) of the prior art with a thicker metal layer. The second type is the probe structure 10 (labeled as B in FIG. 9A) of this embodiment. The third type and the fourth type are unshielded metal needles (labeled as C and D in FIG. 9A). Parameters of the probe structures are listed in the following table.

| | | | Diameter of | Thickness | | |
|---|---|---|---|---|---|---|
| | | Diameter of | insulative | of metal | Length of | Material of |
| No. | Description | metal needle | tube | layer | metal needle | metal needle |
| A | Prior art | 8.0 mil | 26.0 mil | 8.0 mil | 140.0 mil | BeCu |
| B | This | | 10.0 mil | 1.0 μm | | |
| | embodiment | | | | | |
| C | Unshielded | | Without | Without | | |
| D | | | insulative | metal | | |
| | | | tube | layer | | |

In the test, the various probe structures are placed in a probe analyzer (an “Applied Precision point vx3” model probe analyzer is used in this embodiment). Next, the tips of the probe structures touch a pressure sensing device of the probe analyzer; and then, the tips gradually press the pressure sensing device. As can be known from values measured by the pressure sensing device, the prior art probe structure (labeled as A) has a bad resilience and cannot reduce the balance contact force (BCF) of the tip on the pressure sensing device. In contrast, the probe structure 10 of this embodiment and the metal needles labeled as C and D all have a good resilience and can effectively reduce the BCF of the tip on the pressure sensing device. As can be known from this comparison, even though the metal needle 11 of the probe structure 10 of this embodiment is covered with the metal layer 13 and the soft insulative tube 12, there is no significant difference between the resilience of the metal needle 11 and the resilience of a metal needle covered with no material.

FIG. 3 shows a cross sectional view of a probe structure according to the second preferred embodiment of the present invention. In the second embodiment of the present invention, another probe structure 10′ is proposed. The probe structure 10′ is a vertical probe structure, and differs from the probe structure 10 of the first embodiment mainly in that: in addition to the first end-portion 111 and the second end-portion 112, the metal needle 11 of the probe structure 10′ further has a curved portion 113 which is disposed between the first end-portion 111 and the second end-portion 112. The curved portion 113 may further be completely or partially disposed within the through hole 121 of the soft insulative tube 12. The probe structure 10′ may also be called a probe structure of the “Cobra” form.

Because the thickness T of the metal layer 13 is at most 10 micrometers and the soft insulative tube 12 flexes easily, the resilience of the curved portion 113 can still be maintained. Thus, when the metal needle 11 vertically strikes against the electronic component under testing, the curved portion 113 can still be deformed (i.e., compressed) to buffer the force generated when the metal needle 11 strikes against the electronic component under testing. On the other hand, because the metal needle 11 of the probe structure 10′ is also covered by the soft insulative tube 12 and the metal layer 13, the testing signal is less liable to interference or distortion when being transmitted in the metal needle 11.

FIGS. 4A, 4B and 5 show two bottom views and a side view of a probe card according to the third preferred embodiment of the present invention, respectively. In the third embodiment, a probe card 1 is proposed. The probe card 1 may comprise a plurality of the probe structures 10 of the first embodiment and a probe fixture 20. The probe structures 10 are held by the probe fixture 20. The tips 1111 of the probe structures 10 are exposed outside the probe fixture 20.

In more detail, the probe fixture 20 may have a substrate 21 and a holding structure 22. The substrate 21 may be a circuit board or a board capable of transmitting an electrical signal, and has a plurality of metal pads 211 which may be disposed on the top surface and bottom surface of the substrate 21. The holding structure (or a holding ring) 22 is disposed on the substrate 21, and may have a ring shape. The holding structure 22 may be made of ceramic, metal, cured epoxy, or a combination thereof, and can hold the probe structures 10 to keep the probe structures 10 inclined (i.e., non-vertical).

When the probe structures 10 are held, the second end-portions 112 of the metal needles 11 of the probe structures 10 can be electrically connected to the metal pads 211 of the substrate 21 respectively, so that the testing signal can be transmitted to the metal needles 11 via the substrate 21. Each of the second end-portions 112 and the corresponding metal pad 211 can be electrically connected through a direct welding (as shown in FIG. 5), and then the metal pad 211 is electrically connected to a transmission line (e.g., a coaxial cable or a microstrip line) 30 via a conductive via hole 212 of the substrate 21.

On the other hand, the soft insulative tubes 12 and the metal layers 13 of the probe structures 10 can be partially covered by the holding structure 22; that is, the soft insulative tubes 12 and the metal layers 13 are partially covered in the holding structure 22.

In reference to the signal integrity test of the probe card shown in FIG. 9B, the probe card 1 firstly measures variations of drain currents I_{d} of two transistors at a gate voltage V_{g} of −2 V to −0.4 V in the test. Here, the drain voltage V_{d} is 3.5 V and the sources of the transistors are grounded. Six of the probe structures 10 (e.g., six probe structures at the right side shown in FIG. 4B) of the probe card 1 make contact with six contacts of one of the transistors to measure the transistor simultaneously. As shown in FIG. 10, of the six contacts 51 to 56 of the transistor 50, contacts 51, 52, 55 and 56 are each a source contact, the contact 53 is a gate contact, while the contact 54 is a drain contact. The other six probe structures 10 (e.g., six probe structures at the left side shown in FIG. 4B) make contact with six contacts of the other transistor to measure the transistor simultaneously. Then, the probe card 1 measures a single transistor again under the same electrical conditions. In this case, the probe card 1 may only have six probe structures 10.

As revealed by the test results, the drain currents I_{d} (as shown by a solid line with dots in FIG. 9B) obtained when the probe card 1 measures two transistors simultaneously and the drain current I_{d} (as shown by a solid line with diamonds in FIG. 9B) obtained when the probe card 1 measures only a single transistor are very close to each other. On the other hand, the drain currents I_{d} (as shown by a dash line in FIG. 9B) obtained when the prior art probe card (i.e., the unshielded probe card) measures two transistors simultaneously and the drain current I_{d} (as shown by the solid line with diamonds in FIG. 9B) obtained when the prior art probe card measures only a single transistor are significantly different from each other.

As can be known from the above test results, the probe structures 10 of the probe card 1 are not prone to signal coupling therebetween because of the metal layers 13 and the soft insulative tubes 12; thus, the integrity of the testing signal is good. In other words, the electrical property of the electronic product measured by the probe card 1 is accurate. Therefore, accurate test results can also be obtained when the probe card 1 measures two or more objects under simultaneous testing.

It shall be additionally appreciated that the probe card 1 also has a good space transforming ability for the following reason: the thickness of the metal layer 13 of each of the probe structures 10 is only 10 micrometers at most, so each of the probe structures 10 still has a small overall diameter so that the probe structures 10 can be arranged densely. The actual production of the probe card 1 is also good for the following reason: the soft insulative tubes 12 and the metal layers 13 of the probe structures 10 are easy to produce, and the soft insulative tubes 12 and the metal needles 11 are also easy to assemble without the need of a special machine. Furthermore, both an inner diameter d and an outer diameter D of each of the soft insulative tubes 12 are adjustable to impart the soft insulative tube 12 with different characteristic impedances Z₀. A relational expression between the inner diameter, the outer diameter and the characteristic impedance may be as follows (wherein ∈_{τ} represents a dielectric constant of the soft insulative tube 12):

$${Z}_{0} = \frac{1}{2 π} \sqrt{\frac{μ}{ɛ}} ln \frac{D}{d} \approx \frac{138 Ω}{\sqrt{{ɛ}_{τ}}} {log}_{10} \frac{D}{d}$$

FIG. 6A shows a side view of a probe card according to the fourth preferred embodiment of the present invention. In the fourth embodiment, another probe card 2 is proposed. The probe card 2 is similar to the probe card 1 except that: the soft insulative tubes 12 and the metal layers 13 of the probe structures 10 of the probe card 2 are not covered by the holding structure 22 but are outside the holding structure 22. Instead, the first end-portions 111 of the metal needles 11 of the probe structures 10 of the probe card 2 are partially covered by the holding structure 22. On the other hand, each of the second end-portions 112 of the metal needles 11 is electrically connected to the corresponding metal pad 211 via another transmission line 30.

With this arrangement, the metal needles 11 of the probe card 2 can first be fixed to the holding structure 22. Then, the soft insulative tubes 12 are fitted over the second end-portions 112 of the metal needles 11 that protrude from the holding structure 22.

FIGS. 6B to 6D show three side views of the probe card according to the fourth preferred embodiment of the present invention, respectively. In addition to what is shown in FIG. 6A, the probe card 2 may also have other variants. For example, as shown in FIG. 6B, the first end-portion 111 of the metal needle 11 of the probe structure 10 of the probe card 2 protrudes from the soft insulative tube 12 by a distance larger than that shown in FIG. 5. As shown in FIG. 6C, the soft insulative tube 12 and the metal layer 13 of the probe structure 10 of the probe card 2 are covered by the holding structure 22, but the soft insulative tube 12 and the metal layer 13 do not further extend downwards out of the holding structure 22; that is, the holding structure 22 comes into contact with the soft insulative tube 12, the metal layer 13 and the first end-portion 111 of the metal needle 11 simultaneously. As shown in FIG. 6D, the metal layer 13 of the probe structure 10 of the probe card 2 is further covered with a semi-rigid conductive tube or a mesh conductive tube 40, so that the probe structure 10 is less prone to signal coupling therebetween or will not lead to increased signal loss.

As can be known from the above description, the metal needles 11, the soft insulative tubes 12, the metal layers 13 and the holding structure 22 may be fixed to each other in various ways; furthermore, the soft insulative tubes 12 may cover the metal needles 11 by various lengths. Thus, the user can flexibly select the desired fixing way or the desired covering length depending on different objects under testing so that the probe card has a specific space transformer corresponding to the object under testing.

FIGS. 7A and 7B show two side views of a probe card according to the fifth preferred embodiment of the present invention, respectively. In the fifth embodiment, a further probe card 3 is proposed. The probe card 3 is a vertical probe card, and comprises a plurality of the probe structures 10′ of the second embodiment and another kind of probe fixture 20.

In detail, the probe fixture 20 may have an upper plate 23 and a lower plate 24 spaced apart from each other. Both the upper plate 23 and the lower plate 24 can be formed by a ceramic layer and a metal layer. The upper plate 23 has a plurality of conductive blocks (e.g., metal pads) 231 and the lower plate 24 has a plurality of through holes 241. The probe structures 10′ are disposed between the upper plate 23 and the lower plate 24, with the tips 1111 of the probe structures 10′ protruding from the lower plate 24 via the through holes 241 of the lower plate 24. The second end-portions 112 of the probe structures 10′ can come into contact with the conductive blocks 231 to electrically connect the conductive blocks 231.

As shown in FIG. 7A, each of the conductive blocks 231 can be connected to a transmission line (e.g., a coaxial cable) 30 so that the testing signal can be transmitted to the corresponding metal needle 11 via the transmission line 30 and the conductive block 231. As shown in FIG. 7B, the transmission line 30 can further be connected to a metal pad 232 of the upper plate 23. The metal pad 231 is connected to another transmission line (e.g., a microstrip line) 30 so that the testing signal can be transmitted to the corresponding metal needle 11 via the transmission line 30, the metal pad 232 and the conductive block 231.

As probe card 1 or 2, probe card 3 also has good testing signal integrity, space transformer and actual production. The characteristics of the probe cards 1 to 3 and the characteristics of the prior art probe card are listed in the following table. It can be known from the following table that, as compared to the prior art probe card, probe cards 1 to 3 can effectively improve the electrical property of the testing signal, but is only slightly increased in production cost and only slightly decreased in space transformer.

| | | Shielded | | | |
|---|---|---|---|---|---|
| | | | Signal | | Space |
| | Fabri- | | integrity | Production | transformer |
| | cation | Shielding | Electrical | Additional | Additional |
| Type | mode | type | improvement | cost | restriction |
| Lateral | Blade | Microstrip | Bad | Fair | Good |
| | | Coaxial | Good | Bad | Good |
| | Epoxy | Microstrip | Bad | Good | Bad |
| | | Probe | Fair → | Fair → | Bad → |
| | | cards 1, 2 | Good | Good | Good |
| Vertical | Cobra | Probe | N/a → | N/a → | N/a → |
| | | card 3 | Fair | Good | Little |
| | Pogo | Coaxial | Fair | Bad | Bad |
| | Membrane | Microstrip | Fair | Good | Good |
| | MEMS | N/a | N/a | N/a | N/a |

FIGS. 8A to 8C show schematic views of a method for manufacturing a probe structure according to the sixth preferred embodiment of the present invention, respectively. In the sixth embodiment of the present invention, a method for manufacturing a probe structure is proposed, which can be used to manufacture the probe structure of the first embodiment or the second embodiment. The following description will be made by taking the probe structure of the first embodiment as an example.

As shown in FIG. 8A, in the first step, a soft insulative tube 12 is firstly provided, and the soft insulative tube 12 has a through hole 121. Then, as shown in FIG. 8B, in the second step, a metal layer 13 with a thickness T no larger than 10 micrometers is coated on the outer surface 122 of the soft insulative tube 12 by electrolysis plating, electroless plating, evaporating, sputtering or the like. Finally, as shown in FIG. 8C, in the third step, a metal needle 11 is inserted into the through hole 121 of the soft insulative tube 12 in such a way that the tip 1111 of the metal needle 11 protrudes from the through hole 121. Thereby, the probe structure 10 (10′) with good resilience and signal integrity can be produced in a simple way and at an appropriate production cost.

It shall be appreciated that the third step may also be executed after the first step and before the second step; that is, the metal needle 11 is firstly inserted into the through hole 121 of the soft insulative tube 12, and then the metal layer 13 is coated on the outer surface 122 of the soft insulative tube 12.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A probe structure, comprising:
a metal needle, having a first end-portion and a second end-portion opposite to each other, wherein the first end-portion has a tip;
a soft insulative tube, having a through hole in which the metal needle is partially inserted, wherein the tip of the metal needle protrudes from the through hole; and
a metal layer, being coated on an outer surface of the soft insulative tube, being electrically isolated from the metal needle, and having a thickness no larger than 10 micrometers.

2. The probe structure of claim 1, wherein a manufacturing material of the soft insulative tube includes polyimide or PTFE.

3. The probe structure of claim 1, wherein a manufacturing material of the metal layer includes palladium, nickel or gold.

4. The probe structure of claim 1, wherein the first end-portion of the metal needle protrudes from the through hole only at the tip.

5. The probe structure of claim 1, wherein the metal needle further has a curved portion which is disposed between the first end-portion and the second end-portion and within the through hole of the soft insulative tube.

6. The probe structure of claim 1, further comprising a semi-rigid conductive tube or a mesh conductive tube which covers the metal layer.

7. A probe card, comprising:
a probe fixture; and
a plurality of the probe structures of claim 1, being held by the probe fixture, wherein the tips of the probe structures are exposed outside the probe fixture.

8. The probe card of claim 7, wherein the probe fixture includes a substrate and a holding structure, the substrate includes a plurality of metal pads, the holding structure is disposed on the substrate to hold the probe structures, and the second end-portions of the probe structures are electrically connected to the metal pads, respectively.

9. The probe card of claim 8, wherein the soft insulative tubes and the metal layers of the probe structures are partially covered by the holding structure.

10. The probe card of claim 8, wherein the first end-portions of the metal needles are partially covered by the holding structure, and the soft insulative tubes and the metal layers are outside the holding structure.

11. The probe card of claim 8, wherein the first end-portions of the metal needles, the soft insulative tubes and the metal layers all are partially covered by the holding structure.

12. The probe card of claim 8, wherein the holding structure is made of ceramic, metal, cured epoxy, or a combination thereof.

13. The probe card of claim 7, wherein the probe fixture includes an upper plate and a lower plate spaced apart from each other, the lower plate includes a through hole, the probe structures are disposed between the upper plate and the lower plate, and the tips of the probe structures protrude from the lower plate via the through hole of the lower plate.

14. The probe card of claim 7, wherein a manufacturing material of the soft insulative tube includes polyimide or PTFE.

15. The probe card of claim 7, wherein a manufacturing material of the metal layer includes palladium, nickel or gold.

16. The probe card of claim 7, wherein the first end-portion of the metal needle protrudes from the through hole only at the tip.

17. The probe card of claim 7, wherein the metal needle further has a curved portion which is disposed between the first end-portion and the second end-portion and within the through hole of the soft insulative tube.

18. The probe card of claim 1, further comprising a semi-rigid conductive tube or a mesh conductive tube which covers the metal layer.

19. A method for manufacturing a probe structure, comprising:
providing a soft insulative tube which has a through hole;
coating a metal layer with a thickness no larger than 10 micrometers on an outer surface of the soft insulative tube; and
inserting a metal needle into the through hole of the soft insulative tube in such a way that a tip of the metal needle protrudes from the through hole.

20. The method of claim 19, wherein the metal layer is coated on the outer surface of the soft insulative tube by electrolysis plating, electroless plating, evaporating or sputtering.
